(19) United States
(12) Patent Application Publication
(10) Pub. No.: US 2026/0333835 A1
(43) Pub. Date: Oct. 22, 2026

(54) SILICIDE REGIONS AND THE METHODS OF FORMING THE SAME

(71) Applicant: Taiwan Semiconductor Manufacturing Co., Ltd., Hsinchu (TW)

(72) Inventors: Hsin Wang, New Taipei City (TW); Kai-Chieh Yang, New Taipei City (TW); Shih-Jung Ho, Hsinchu (TW); Ku-Feng Yang, Baoshan Township (TW); Wei-Yen Woon, Taoyuan City (TW); Szuya Liao, Zhubei (TW)

(21) Appl. No.: 19/728,658

(22) Filed: Jul. 2, 2026

Related U.S. Application Data
(63) Continuation of application No. 19/045,808, filed on Feb. 5, 2025.
(60) Provisional application No. 63/718,021, filed on Nov. 8, 2024.

(51) Int. Cl. H10D 84/01; H10D 30/00; H10D 30/01; H10D 62/10; H10D 62/13; H10D 64/01; H10D 64/23; H10D 84/85; H10P 50/28

(52) U.S. Cl. CPC H10D 84/017; H10D 30/019; H10D 64/0112; H10D 64/256; H10D 84/0186; H10P 50/283; H10D 30/502; H10D 62/121; H10D 62/151; H10D 84/851; H10D 84/856

(57) ABSTRACT

A method includes forming a source/drain region, forming a contact etch stop layer over the source/drain region, forming an inter-layer dielectric over the contact etch stop layer, forming a first contact plug in the inter-layer dielectric and the contact etch stop layer, and performing an etching process to form a trench in the inter-layer dielectric and the contact etch stop layer. The source/drain region and the first contact plug are exposed to the trench. The method further includes performing a silicide formation process to form a silicide region on a surface of the source/drain region, and etching a metal layer that is deposited on dielectric regions and in the trench. The dielectric regions are exposed at a time the silicide formation process is started. A second contact plug is formed in the trench.

### PRIORITY CLAIM AND CROSS-REFERENCE

This application is a continuation of U.S. patent application Ser. No. 19/045,808 filed on Feb. 5, 2025, which application claims the benefit of the provisionally filed U.S. Patent Application No. 63/718,021, filed on Nov. 8, 2024, which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B through FIG. 14 are views of intermediate stages in the formation of CFETs and silicide regions in accordance with some embodiments.

FIGS. 15 through 19 are views of intermediate stages in the formation of CFETs and silicide regions in accordance with some embodiments.

FIGS. 20 and 21 illustrate zeta potentials of TiO₂ and WO₃ in accordance with some embodiments.

FIG. 22 illustrates a distribution profile of an element in a passivation layer in accordance with some embodiments.

FIG. 23 illustrates a flow chart for forming CFETs and silicide regions in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs), silicide regions, contact plugs, and the method of forming the same are provided. In accordance with some embodiments of the present disclosure, the silicide regions are formed with metal being deposited, and at the same time the metal reacts with epitaxy semiconductor to form a silicide region. A dry etching process may be performed to remove the metal undesirably deposited on the surfaces of dielectric regions. A nitrogen-treatment process is performed to form a metal silicon nitride layer on the silicide region, which causes a metal nitride layer to form on an exposed metallic region. A subsequent wet etching process may be used to remove the metal nitride layer.

It is appreciated that while the CFET includes Gate-All-Around (GAA) transistors (such as nanostructure-FETs) are discussed, the concept of the present disclosure can also be applied to the formation of contact plugs connecting to other types of transistors such as planar transistors, Fin Field-Effect Transistors (FinFETs), and the like. Throughout the description, the terms “FET” and “transistor” are used interchangeably.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

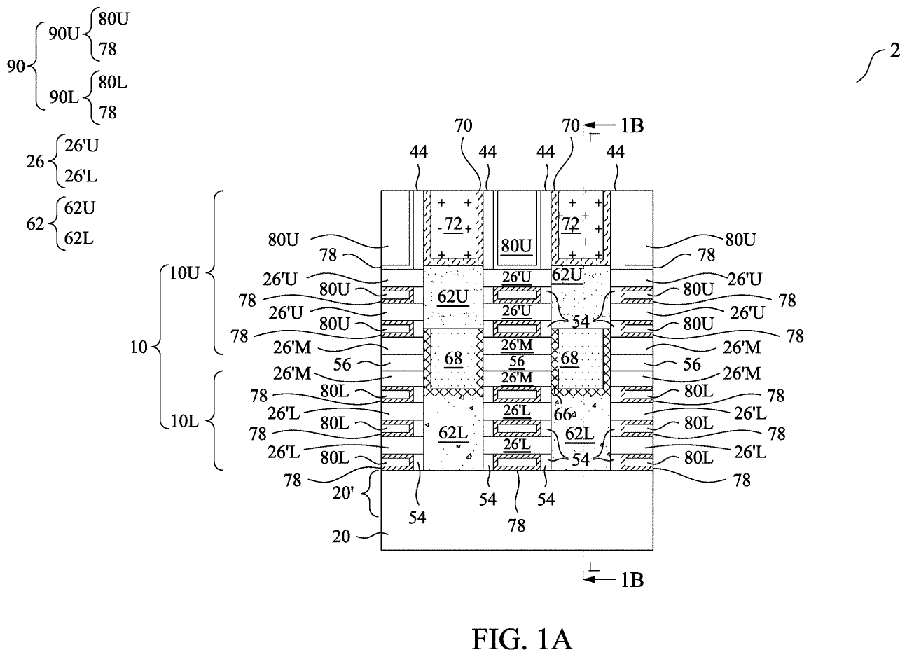

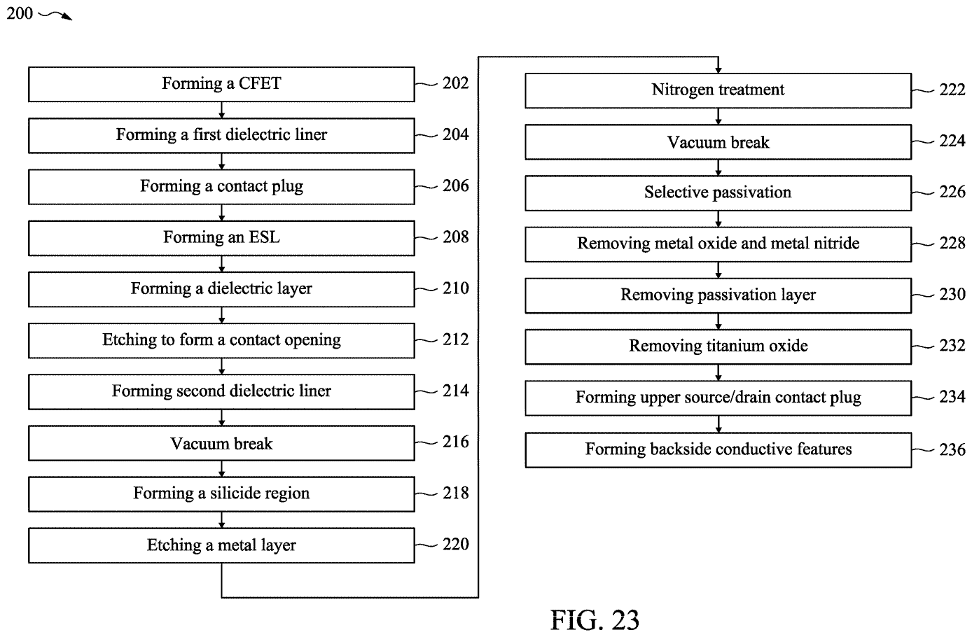

FIGS. 1A and 1B through FIG. 14 illustrate the cross-sectional views of intermediate stages in the formation of CFETs and silicide regions in accordance with some embodiments of the present disclosure. The corresponding processes are also reflected schematically in the process flow shown in FIG. 23.

FIG. 1A illustrates the formation of an example CFET 10 (including FETs (transistors) 10U and 10L) in accordance with some embodiments. The respective process is illustrated as process 202 in the process flow 200 as shown in FIG. 23. CFET 10 may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

As shown in FIG. 1A, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multilayered or gradient substrate may also be used. In some embodiments, the semiconductor material of the substrate 20 may include silicon, germanium, carbon-doped silicon, a III-V compound semiconductor, or the like, or combinations thereof.

In the illustrated example, each of the upper FET 10U and lower FET 10L includes two semiconductor layers 26′U and 26′L, respectively, as the channels. It should be appreciated that the upper FET 10U and lower FET 10L may include any number of channel regions such as 1, 2, 3, or more. The portions of the gate stack 90 that are overlying and/or underlying the channel regions 26 form multilayer stacks with the corresponding channel regions 26′U and 26′L.

Gate stacks 90 (including upper gate stacks 90U and lower gate stacks 90L) are formed between semiconductor layers 26. Upper gate stacks 90U includes gate dielectrics 78 and upper gate electrodes 80U. Lower gate stacks 90L includes gate dielectrics 78 and lower gate electrodes 80L. Gate dielectrics 78 encircle (when viewed in side views) the respective semiconductor nanostructures 26. Gate electrodes 80 (including a lower gate electrode 80L and an upper gate electrode 80U) are over the gate dielectrics 78. Dielectric isolation layers 56 are formed to isolate the gate stack 90U of the upper FETs 10U from the gate stack 90L of the lower FETs 10L. Dummy semiconductor layers 26′M may be formed to contact dielectric isolation layers 56.

Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context.

Inner spacers 54, which are dielectric spacers, are formed on the opposing sides of the portions of gate stacks 90, which portions are between semiconductor layers 26. Inner spacers 54 electrically insulate the source/drain regions 62L and 62U from the corresponding parts of gate stacks 90 to prevent and reduce leakage.

Gate spacers 44 are formed over the multilayer stacks and on the sidewalls of gate stacks 90. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as Chemical Vapor Deposition (CVD), Atomic Layer Deposition (ALD), or the like.

Source/drain regions 62L and 62U are formed laterally between the multilayer stacks that comprise channel regions 26 and gate stacks 90. Lower source/drain regions 62L are formed over and contacting a substrate, which includes semiconductor substrate 20. The lower source/drain regions 62L are further in contact with the lower semiconductor nanostructures 26′L and are not in contact with the upper semiconductor nanostructures 26′U.

The lower source/drain regions 62L are epitaxially grown, and have a conductivity type that is suitable for the device type (p-type or n-type) of the lower nanostructure-FETs. When lower source/drain regions 62L are n-type source/drain regions, the respective material may include silicon or carbon-doped silicon, which is doped with an n-type dopant such as phosphorous, arsenic, or the like. When lower source/drain regions 62L are p-type source/drain regions, the respective material may include silicon or silicon germanium, which is doped with a p-type dopant such as boron, indium, or the like. The lower source/drain regions 62L may be in-situ doped, and may be, or may not be, implanted with the corresponding p-type or n-type dopants

A first contact etch stop layer (CESL) 66 and a first ILD 68 are formed over the lower source/drain regions 62L. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like. The first CESL 66 may be formed of a dielectric material having a high etching selectivity from the etching of the first ILD 68. For example, the first CESL 66 may comprise silicon nitride, silicon oxide, silicon oxynitride, or the like, which may be formed by any suitable deposition process, such as CVD, ALD, or the like.

Upper source/drain regions 62U are formed overlapping the first CESL 66 and the first ILD 68, and overlapping the lower source/drain regions 62L. The materials of upper source/drain regions 62U may be selected from the same candidate group of materials for forming lower source/drain regions 62L, depending on the desired conductivity type of upper source/drain regions 62U.

The conductivity type of the upper source/drain regions 62U may be opposite the conductivity type of the lower source/drain regions 62L. Alternatively stated, the upper source/drain regions 62U may be oppositely doped than the lower source/drain regions 62L. The upper source/drain regions 62U may be in-situ doped, and/or may be implanted, with an n-type or p-type dopant.

A second CESL 70 and a second ILD 72 are formed over the upper source/drain regions 62U. The materials and the methods may be similar to, and may be the same as or different from, the materials and the formation methods of the first CESL 66 and first ILD 68, respectively, and are not discussed in detail herein.

FIG. 1B illustrates a cross-sectional view of the structure as shown in FIG. 1A. The illustrated cross-section may be the cross-section 1B-1B as in FIG. 1A. Dielectric isolation regions 32, also sometimes referred to as Shallow Trench Isolation (STI) regions 32, are formed over substrate 20. Semiconductor strips 20′ (also refer to FIG. 1A) are formed between the STI regions 32. Fin spacers 45 may be formed on the sidewalls of the top portions of semiconductor strips 20′. Lower source/drain regions 62L, the first CESL 66, the first ILD 68, the upper source/drain regions 62U, the second CESL 70, and the second ILD 72 are illustrated.

FIG. 1B further illustrates the formation of contact plug 116. In accordance with some embodiments, the formation of contact plug 116 includes etching the second ILD 72, the second CESL 70, the first ILD 68, and the first CESL 66, so that a trench is formed. The trench may extend to an intermediate level between the top surface and the bottom surface of isolation region 32.

Dielectric liner 114 is formed in the trench. The respective process is illustrated as process 204 in the process flow 200 as shown in FIG. 23. In accordance with some embodiments, the formation of dielectric liner 114 includes a deposition process using a conformal deposition method such as Chemical Vapor Deposition (CVD), Atomic Layer Deposition (ALD), Physical Vapor Deposition (PVD), or the like to form a conformal dielectric layer. In accordance with some embodiments, the material of dielectric liner 114 may include silicon nitride, a metal oxide of a metal such as Hf, Ti, Al, W, Nb, Re, or the like, a metal nitride of a metal such as Hf, Ti, Al, W, Nb, Re, or the like, or combinations thereof.

Contact plug 116 is then formed. The respective process is illustrated as process 206 in the process flow 200 as shown in FIG. 23. Contact plug 116 may also be referred to as a vertical local interconnect. In accordance with some embodiments, contact plug 116 comprises a metal such as tungsten, molybdenum, ruthenium, iridium, or the like, or alloys thereof. In accordance with some embodiments, contact plug 116 has a single-layer structure, with the entire contact plug 116 being formed of a homogeneous material such as aforementioned.

In accordance with alternative embodiments, the formation of contact plug 116 may include depositing a barrier layer, which may comprise titanium, titanium nitride, tantalum, tantalum nitride, or the like. Next, a metallic material is deposited over and in contact with the barrier layer. The metallic material may include tungsten, cobalt, copper, nickel, molybdenum, ruthenium, iridium, or the like, or a combination thereof.

After the deposition of the materials for forming contact plug 116, a planarization process such as a CMP process or a mechanical grinding process is performed to remove excess portions of the deposited material(s), leaving contact plug 116. The contact plug 116 is thus encircled by the dielectric liner 114. The top surfaces of contact plug 116 and dielectric liner 114 are thus coplanar, and may further be coplanar with the top surface of the second ILD 72 when the second ILD 72 is the top layer in the structure.

As shown in FIG. 1B, etch stop layer (ESL) 118 is formed. The respective process is illustrated as process 208 in the process flow 200 as shown in FIG. 23. Etch stop layer 118 may comprise AlN, AlO, SiOC, or the like, or multilayers thereof. Dielectric layer 120 is deposited over etch stop layer 118. The respective process is illustrated as process 210 in the process flow 200 as shown in FIG. 23. Dielectric layer 120 may comprise silicon oxide, silicon nitride, silicon oxynitride, silicon carbide, or the like. A patterned etching mask 121, which may comprise a photoresist, is formed over dielectric layer 120.

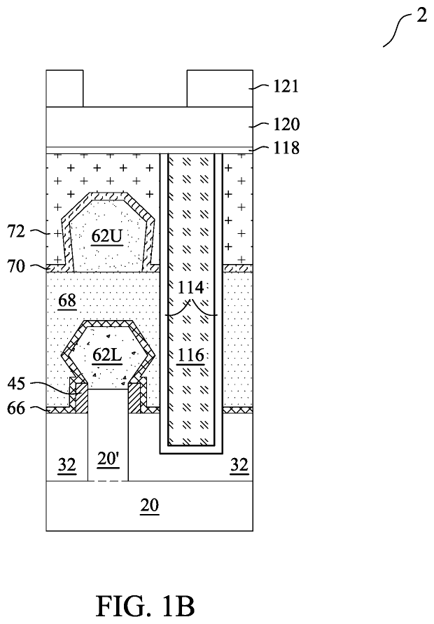

As shown in FIG. 2, etch stop layer 118 and dielectric layer 120 are patterned through etching to form contact opening (trench) 122, through which the second ILD 72 and contact plug 116 are exposed. The respective process is illustrated as process 212 in the process flow 200 as shown in FIG. 23. Contact opening 122 is formed through etching processes. In the etching processes, the underlying second ILD 72, second CESL 70, contact plug 116, and dielectric liner 114 are exposed. The second ILD 72 and the second CESL 70 are etched, so that the upper source/drain region 62U is exposed. The etching stops on the top surface of the upper epitaxy source/drain region 62U. Dielectric liner 114 and contact plug 116 are also exposed. The patterned etching mask 121 (FIG. 1B) is then removed.

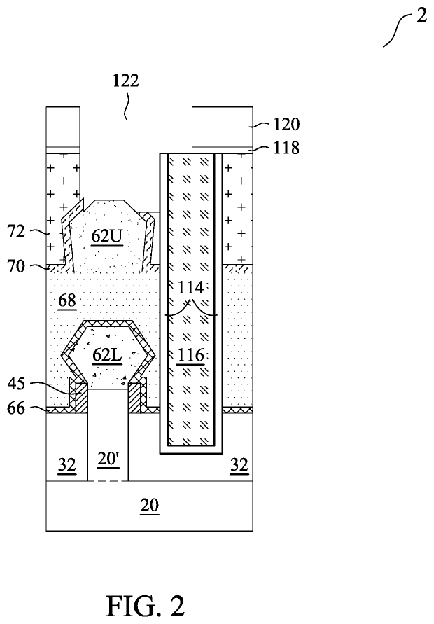

Referring to FIG. 3, dielectric liners 124 are formed. The respective process is illustrated as process 214 in the process flow 200 as shown in FIG. 23. In accordance with some embodiments, the formation of dielectric liners 124 includes depositing a conformal layer through a conformal deposition process, for example through ALD, CVD, PVD, or the like. An anisotropic etching process is then performed to remove the horizontal portion of the conformal layer, leaving the vertical portions as the dielectric liners 124. In the anisotropic etching process, the exposed portions of dielectric liner 114 may also be recessed.

The material of the dielectric liners 124 may be selected from the same group of candidate materials for forming dielectric liner 114, and may be the same as or different from the material of dielectric liner 114. For example, dielectric liners 124 may be formed of and/or comprise silicon nitride.

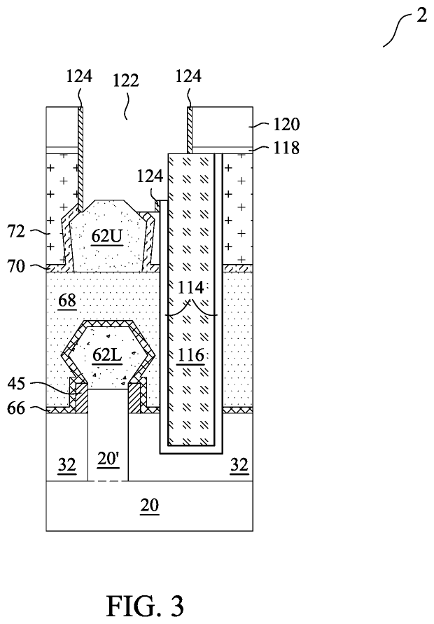

A vacuum break process may occur in order to transfer the respective wafer 2 for the subsequent formation of silicide regions. The respective process is illustrated as process 216 in the process flow 200 as shown in FIG. 23. FIG. 4 illustrates the formation of silicon oxide layer 126 on the exposed surface of upper source/drain region 62U due to oxidation. Metal oxide layer 128 is also formed on the exposed surface of contact plug 116 due to the oxidation of a surface layer of contact plug 116. Metal oxide layer 128 thus comprises the oxide of the metal in contact plug 116. For example, when contact plug 116 comprises tungsten, metal oxide layer 128 comprises tungsten oxide (including WO₃).

A pre-clean process may be performed, for example, using the mixture of HF and NH₃ gases. Silicon oxide layer 126 is thus removed, and the underlying upper source/drain region 62U is exposed. Metal oxide layer 128, on the other hand, may not able to be removed by the pre-clean process.

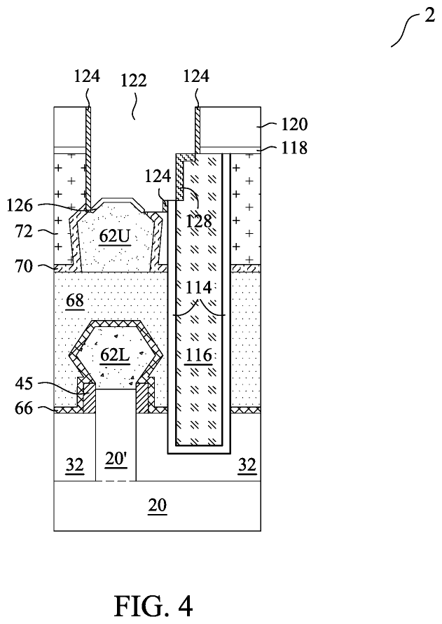

Referring to FIG. 5, silicide region (layer) 130 is formed. The respective process is illustrated as process 218 in the process flow 200 as shown in FIG. 23. In accordance with some embodiments, the formation of silicide region 130 may include conducting a process gas, which includes a metal-containing precursor, into the respective reaction chamber. The metal in the metal-containing precursor is deposited on upper source/drain region 62U, and reacts with a surface portion of the upper source/drain region 62U to form silicide region 130.

In accordance with some embodiments, the metal-containing precursor is a titanium-containing precursor such as TiCl₄, titanium tetraisopropoxide (Ti[OCH(CH₃)₂]₄ (TTIP), tetrakis(dimethylamino)titanium (Ti[N(CH₃)₂]₄, (TDMAT)), or the like. Silicide region 130 thus may include titanium silicide (TiSi) in accordance with some embodiments. Hydrogen (H₂) may also be conducted into the reaction chamber. In accordance with other embodiments, the metal-containing precursor may comprise other types of metals such as V, Zn, Nb, Al, or the like.

The process gas may be free from or substantially free from (for example, with the flow rate percentage smaller than 1 percent) nitrogen-containing gases such as N₂, NH₃, and the like. The reaction is performed with plasma turned on. The respective wafer 2 may be heated, for example, to a temperature in a range between about 300 °C and about 600 °C. In accordance with some embodiments, after the silicidation process, no additional anneal process is performed for the formation of silicide region 130.

The formation of silicide region 130, due to the using of the metal-containing precursor such as TiCl₄, may have the effect of etching and removing metal oxide layer 128.

In accordance with some embodiments, at the same time metal silicide region 130 is formed, metal layer 132 is also deposited on the surfaces of the exposed dielectric materials such as dielectric liners 124 and dielectric layer 120. Metal layer 132 thus comprises the same metal as silicide region 130. Metal layer 132 may also be deposited on contact plug 116. For example, metal layer 132 may comprise titanium (Ti), which may be in the form of elemental metal (without forming metal compound with other elements).

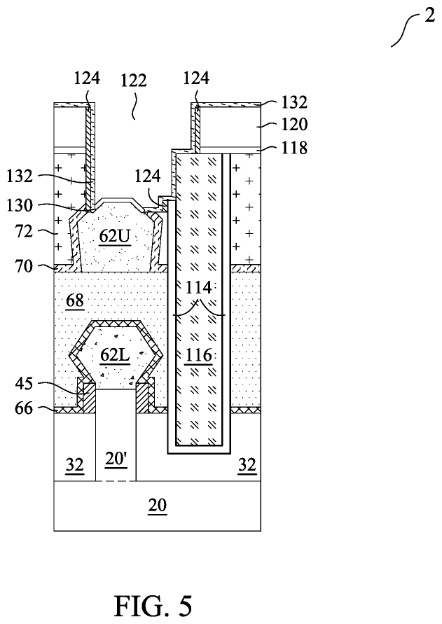

Referring to FIG. 6, an etching process 134 is performed to selectively etch metal layer 132, while silicide region 130 and the subsequently exposed dielectric regions such as dielectric liners 124 are not etched. The respective process is illustrated as process 220 in the process flow 200 as shown in FIG. 23. Contact plug 116 is revealed again as a result of the etching of metal layer 132. In accordance with some embodiments, the selective etching process is performed through a soaking process using an etching gas comprising a metal halide(s). The result structure is shown in FIG. 6.

The metal halide may comprise titanium chloride (TiCl₄), while other metal halides such as nickel halide, Molybdenum halide hafnium halide, tungsten halide, or the like, or combinations thereof may be used. When TiCl₄ is used, the titanium chloride may react with elemental titanium to form a TiClₓ gas, wherein value x may be 2, 3, or the like. The reaction formula may be Ti(s)+TiCl₄(g)→TgiClₓ(g), with letter “s” and “g” representing “solid” and “gas,” respectively.

During the etching process 134, no plasma is generated. There may not be RF power applied, or an RF power may be applied but is not high enough to generate plasma. Also, there may not be Ar introduced, and there may not be hydrogen (H₂) introduced. In accordance with some embodiments, the etching may be performed with wafer 2 being heated, for example, to a wafer temperature in the range between about 300 °C and about 600 °C.

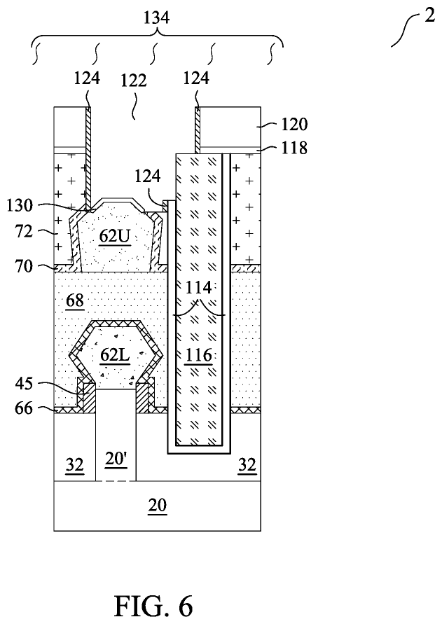

Next, as shown in FIG. 7, a nitrogen-treatment process 136 (also referred to as a nitriding process 136 or nitridation process 136) is performed. The respective process is illustrated as process 222 in the process flow 200 as shown in FIG. 23. The nitrogen-treatment process 136 is performed in-situ with the formation of silicide region 130 and the etching of metal layer 132, with no vacuum break in between. The nitrogen-treatment process 136 may be performed using a nitrogen-containing gas such as N₂, NH₃, and/or the like as a process gas. The nitrogen-treatment process 136 may be performed using plasma treatment and/or thermal treatment. When the thermal treatment is adopted, the wafer temperature may be in the range between about 300 °C and about 600 °C.

As a result of the nitrogen-treatment process 136, metal silicon nitride layer 138 is formed on the silicide region 130 due to the reaction of nitrogen with a surface portion of silicide region 130. Metal silicon nitride layer 138 has the function of blocking oxygen from reaching silicide region 130 in subsequent vacuum break. Metal silicon nitride layer 138 comprises the same metal as silicide region 130. For example, when silicide region 130 comprises titanium silicide (TiSi), metal silicon nitride layer 138 comprises TiSiN.

In the processes as discussed above (FIGS. 5 and 6), metal layer 132 is removed before the nitrogen-treatment process 136. It is appreciated that if metal layer 132 is not removed, nitrogen-treatment process 136 will result in metal layer 132 to be converted into a metal nitride layer such as titanium nitride layer. The titanium nitride layer is difficult to remove since the etching selectivity between silicide region 130 and the titanium nitride layer is low, and the removal of the titanium nitride layer may cause the damage of silicide region 130. Accordingly, in accordance with the embodiments, the nitrogen-treatment process 136 is performed after the removal of metal layer 132, and the silicide region 130 is formed without nitrogen treatment to avoid the formation of metal nitride.

The nitrogen-treatment process 136 also results in metal nitride layer 140 to be formed on the surface of contact plug 116 due to the nitriding of the surface portion of contact plug 116. For example, when contact plug 116 comprises tungsten, metal nitride layer 140 may comprise tungsten nitride (WN).

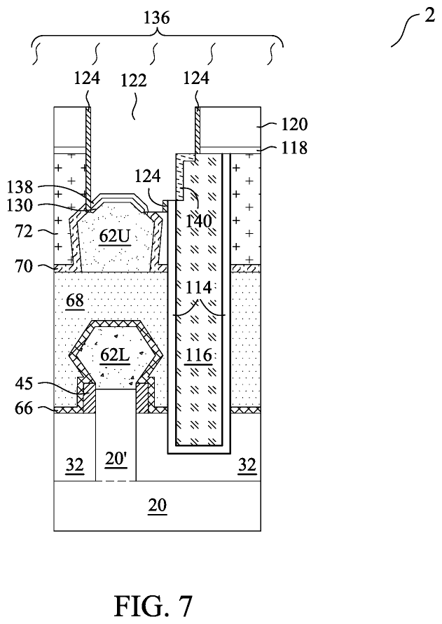

After the nitrogen-treatment process 136, a vacuum break process is performed. The respective process is illustrated as process 224 in the process flow 200 as shown in FIG. 23. The resulting structure is shown in FIG. 8. As a result of the vacuum break, metal oxide layer 142 is formed over metal silicon nitride layer 138. Metal oxide layer 142 may comprise the metal oxide of the same metal as in silicide region 130 and the metal silicon nitride layer 138. For example, when silicide region 130 comprises TiSi, metal oxide layer 142 may comprise TiOₓ, with the value “x” representing the relative atomic ratio of oxygen to titanium.

Due to the vacuum break process, a surface portion of metal nitride layer 140 that is exposed to open air is also oxidized to form metal oxide layer 144 on the surface of metal nitride layer 140. Metal oxide layer 144 thus comprises the same metal (such as tungsten) as metal nitride layer 140. Accordingly, metal oxide layer 144 may comprise WO_{y}, with the value “y” representing the relative atomic ratio of oxygen to the metal (such as W) in metal oxide layer 144. Metal oxide layer 144 may comprise a small amount of nitrogen in addition to oxygen.

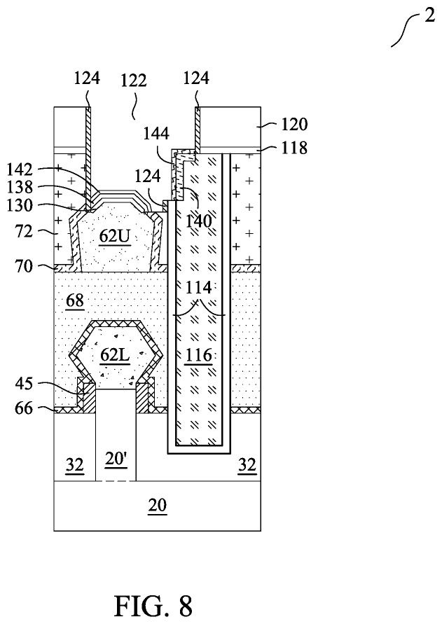

FIG. 9 illustrates a selective passivation process 146 in accordance with some embodiments. The respective process is illustrated as process 226 in the process flow 200 as shown in FIG. 23. Passivation layer 148 is selectively formed on metal oxide layer 142, but not on metal oxide layer 144 and the exposed dielectric features such as dielectric liners 124. The selective passivation process 146 may be performed adopting the different zeta potentials of the metal in metal oxide layer 142 (such as Ti) and the metal (such as W) in metal oxide layer 144. In the subsequent discussion, it is assumed that metal oxide layer 142 comprises titanium oxide, and metal oxide layer 144 comprises tungsten oxide.

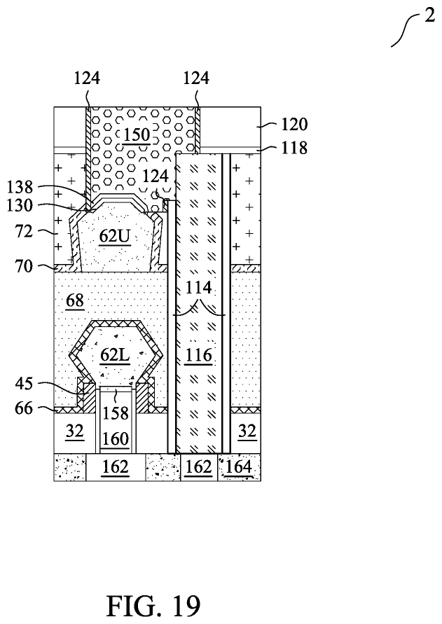

FIG. 20 illustrates the zeta potential of titanium oxide (TiO₂) as a function of pH values of chemical solutions when the titanium oxide is exposed to the chemical solutions. The zeta potential of titanium oxide has a positive value when the pH value is low (acidic), for example, when in the range between about 2 and about 6. The zeta potential of titanium oxide has a negative value when the pH value is high (alkaline).

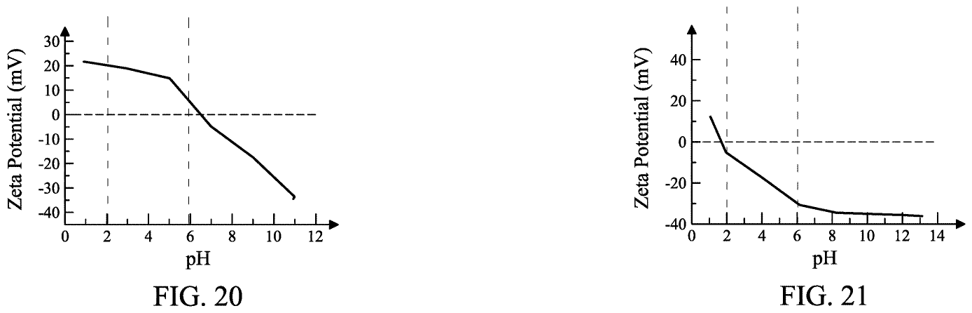

FIG. 21 illustrates the zeta potential of tungsten oxide (WO₃) as a function of pH values of chemical solutions when the tungsten oxide is exposed to the chemical solutions. The zeta potential of tungsten oxide has a negative value when the pH value is low (acidic), for example, when in the range between about 2 and about 6. The zeta potential of tungsten oxide also has a negative value when the pH value is high (alkaline).

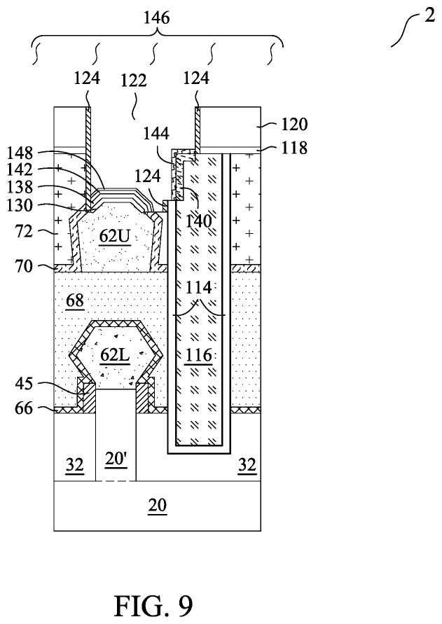

Comparing FIGS. 20 and 21, it is noticed that when the chemical solution is acidic, for example, in the range between about 2 and about 6, there is adequate difference between the zeta potential values of titanium oxide and the zeta potential values of tungsten oxide, with the zeta potential values of titanium oxide being positive, and the zeta potential values of tungsten oxide being negative. When some chemicals are added to the chemical solution, these chemicals tend to adhere on the surface that has the positive zeta potential, in this case, the surface of titanium oxide, and not on the surfaces that have negative zeta potential (such as tungsten oxide). The adhered chemicals thus form a passivation layer 148 (FIG. 10), which is selectively formed on the surface of titanium oxide, but not on the surface of metal oxide layer 144 (such as tungsten oxide), and not on the surfaces of exposed dielectric materials.

In accordance with some embodiments, the chemical solution used for the selective formation of passivation layer 148 may comprise an acid comprising HCl, H₂SO₄, and/or the like, with the pH value of the chemical solution being adjusted to the range between about 2 and about 6. The chemical that is used to adhere to the surface of metal oxide layer 142 (such as titanium oxide) to form the passivation layer 148 may be selected from the group consisting of phosphoric acid, silane coupling agents, polyacrylic acid (with formula (C₃H₄O₂)), and combinations thereof.

In accordance with other embodiments, some fluorine compounds that can effectively passivate titanium oxide by forming protective layers or strong chemical bonds with it surface may also be used to form passivation layer 148. These chemicals do not provide the same passivating effects on WO₃ due to differences in surface chemistry and reactivity.

The wafer 2 as shown in FIG. 8 may be soaked in the chemical solution, so that the passivation layer 148 is formed. The soaking process may last for a period of time in the range between about 10 seconds and about 600 seconds.

Passivation layer 148, depending on the chemicals in the chemical solution, may comprise elements selected from the group consisting of phosphorous, carbon, fluorine, sulfur, and/or the like. The elements in passivation layer 148 may (or may not) diffuse into the underlying metal oxide layer 142 and metal silicon nitride layer 138.

An etching process is then performed to remove the metal oxide layer 144 and metal nitride layer 140. The respective process is illustrated as process 228 in the process flow 200 as shown in FIG. 23. The resulting structure is shown in FIG. 10. In accordance with some embodiments, the etching process may be performed through a wet etching process. The wet etching process may be performed using a mixture of ozonated DI-water (de-ionized water, DiO₃) and hot DI-water. The temperature of the hot DI-water may be in the range between about room temperature (such as about 25 °C) and about 80 °C. The metal oxide layer 144 may be dissolved in hot DI-water, which may have a pH value in the range between about 5.5 and 6.9. Accordingly, the metal oxide layer 144 is first removed, exposing metal nitride layer 140.

The DiO₃ has the function of oxidizing the metal silicon nitride layer 140 into a metal oxide. For example, the tungsten nitride in the metal silicon nitride layer 140 may be oxidized into tungsten oxide (WO₃), which can be dissolved in hot DI-water. Accordingly, by using the mixture of the DiO₃ and the hot DI-water, both of the metal oxide layer 144 and metal nitride layer 140 are removed.

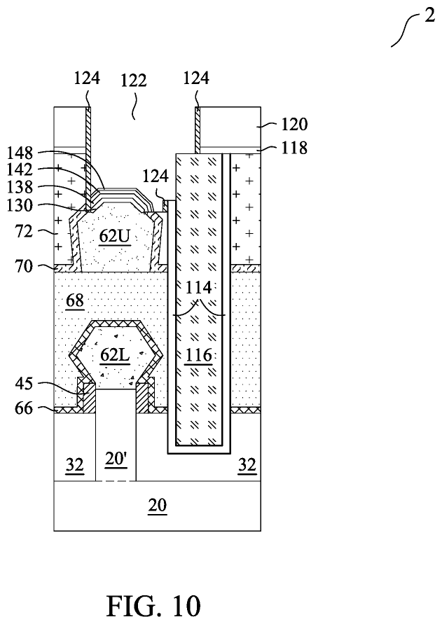

In accordance with some embodiments, after the metal oxide layer 144 and metal nitride layer 140 are removed through the wet etching process, passivation layer 148 is removed. The respective process is illustrated as process 230 in the process flow 200 as shown in FIG. 23. The resulting structure is shown in FIG. 11. The removal of passivation layer 148 may be achieved through a rinsing process using deionized water, followed by using an organic solvent(s) such as ethanol, isopropanol, acetone, or the like to dissolve and remove the passivation layer.

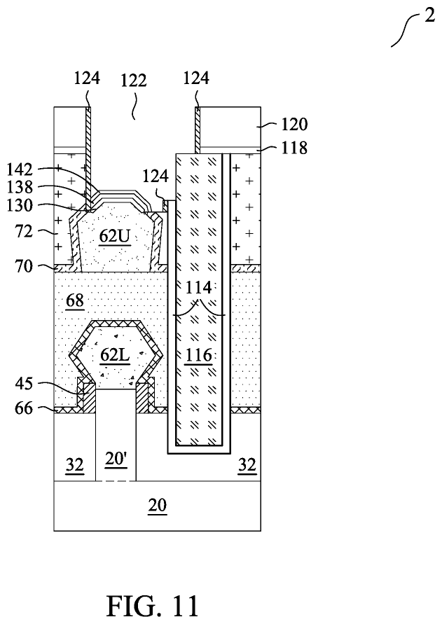

The metal oxide layer 142 (such as a titanium oxide layer) is then removed. The resulting structure is shown in FIG. 12. The respective process is illustrated as process 232 in the process flow 200 as shown in FIG. 23. In accordance with some embodiments, the removal of the titanium oxide may be performed using a plasma generated using the mixture of N₂ and H₂. The metal silicon nitride layer 138 (such as TiSiN) is thus exposed.

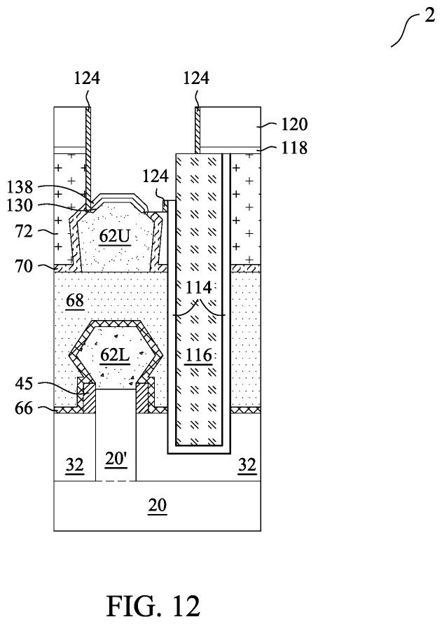

Next, referring to FIG. 13, contact plug 150 is formed. Contact plug 150 may be referred to as an upper source/drain contact plug. The respective process is illustrated as process 234 in the process flow 200 as shown in FIG. 23. In accordance with some embodiments, contact plug 150 comprise a metal such as tungsten, molybdenum, ruthenium, iridium, or the like, or alloys thereof. In accordance with some embodiments, contact plug 150 has a single-layer structure, with the entire contact plug 150 being formed of a homogeneous material such as aforementioned.

Further referring to FIG. 13, after the deposition of the material for forming contact plug 150, a planarization process such as a CMP process or a mechanical grinding process is performed to remove excess portions of the deposited material(s), leaving contact plug 150. The contact plug 150 is encircled by dielectric liners 124. The top surfaces of contact plug 150 and dielectric liners 124 are thus coplanar, and may further be coplanar with the top surface of the dielectric layer 120.

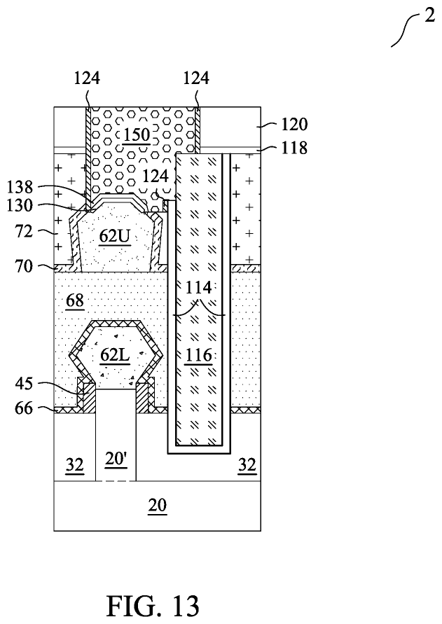

FIG. 14 illustrates the formation of backside conductive features, which are electrically connected to lower source/drain regions 62L and contact plug 116. The respective process is illustrated as process 236 in the process flow 200 as shown in FIG. 23. In accordance with some embodiments, a thinning process is performed (for example, through a CMP process and/or an etching process(es)) to remove substrate 20, exposing contact plug 116.

Semiconductor strip 20′ (FIG. 13) is etched to form a backside opening, through which the bottom of lower source/drain region 62L is exposed. Silicide region 158 is formed underlying and contacting the bottom surface of lower source/drain region 62L. Backside contact plug 160 is formed to fill the remaining backside contact opening. The backside contact plug 160 is in contact with silicide regions 158. Backside contact plug 160 may be formed of a homogeneous metallic material, which may comprise tungsten, cobalt, ruthenium, or the like. There may be, or may not be, a dielectric liner formed to encircle backside contact plug 160.

Dielectric layer 164 is then deposited. Backside redistribution lines 162 (conductive features 162) are formed on the backside of CFETs, and are formed in dielectric layer 164. Backside redistribution lines 162 are electrically connected to contact plug 116 and lower source/drain region 62L.

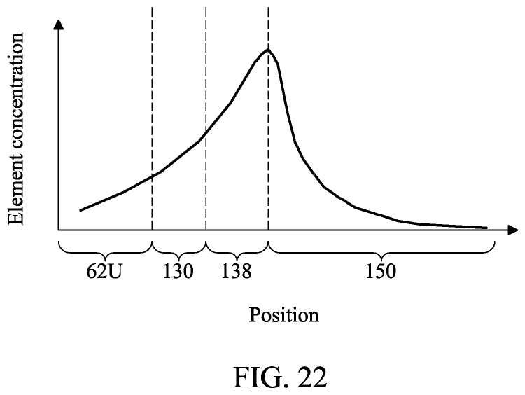

FIG. 22 illustrates the distribution of the element in passivation layer 148 in accordance with some embodiments. The element may include the elements in the passivation layer 148, which may be selected from the group of carbon, fluorine, phosphorus, and combinations thereof. Although passivation layer 148 and the underlying metal oxide layer 142 (FIG. 10) are removed in later processes, the element in the passivation layer 148 may be diffused into the metal silicon nitride layer 138 and silicide region 130, and possibly into upper semiconductor region 62U. Also, since the element is diffused from metal silicon nitride layer 138 after the removal of passivation layer 148 and the underlying metal oxide layer 142, the distribution in contact plug 150 has a sharper falling and lower concentrations than in metal silicon nitride layer 138, silicide region 130, and upper source/drain region 62U. The peak of the element may be at the interface between metal silicon nitride layer 138 and contact plug 150.

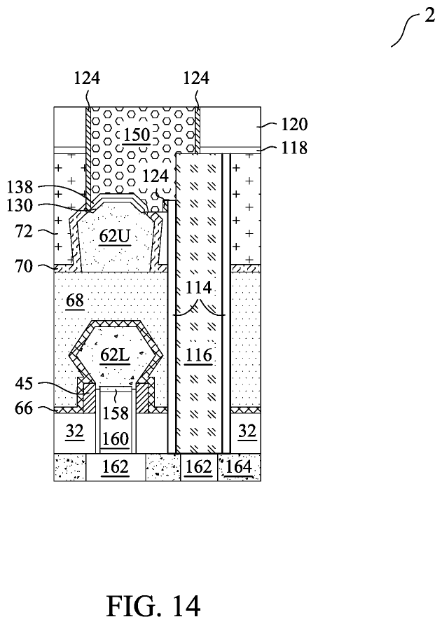

FIGS. 15 through 19 illustrate the cross-sectional views of intermediate stages in the formation of a CFET in accordance with alternatively embodiments of the present disclosure. In accordance with these embodiments, the metal oxide layer 144 and the metal silicon nitride layer 140 are removed without forming a passivation layer to protect the metal oxide layer 142. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

The initial steps of these embodiments are essentially the same as shown in FIGS. 1A and 1B through 8. The resulting structure is also shown in FIG. 15, which is the same as the structure shown in FIG. 8.

A wet etching process is performed to remove the metal oxide layer 144 and the metal silicon nitride layer 140, and the resulting structure is shown in FIG. 15. The wet etching process may be essentially the same as the wet etching process as discussed referring to FIG. 10. For example, the wet etching process may be performed using the mixture of the DiO₃ and the hot DI-water. Accordingly, both of the metal oxide layer 144 and metal nitride layer 140 may be removed.

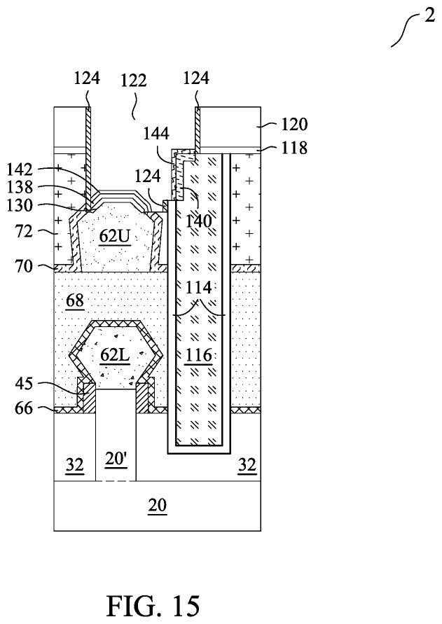

During the wet etching process, there is an etching selectivity between the etching of metal oxide layer 144 and metal nitride layer 140 and the etching of metal oxide layer 142. Metal oxide layer 142 has a lower etching rate than metal oxide layer 144 and metal nitride layer 140, and thus in the embodiments as shown in FIG. 16, metal oxide layer 142 acts as a protection layer protecting the underlying metal silicon nitride layer 138 from being damaged. Alternatively, in the embodiments in which the etching rate of metal oxide layer 142 is not low enough, the embodiments as shown in FIG. 10 is adopted, and passivation layer 148 (FIG. 10) may be further formed to provide enough protection.

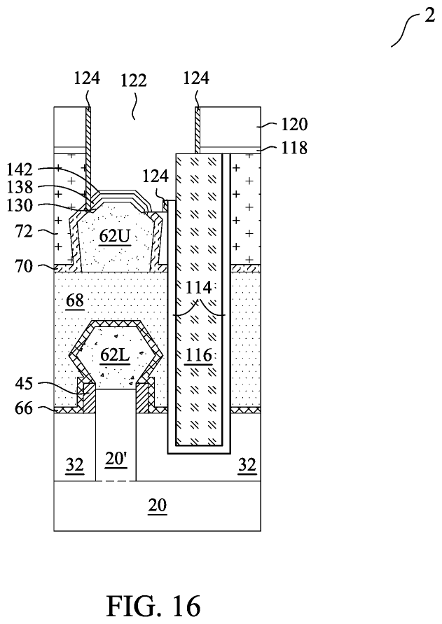

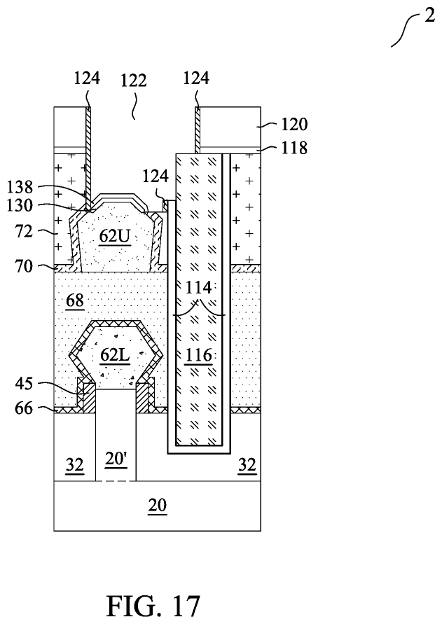

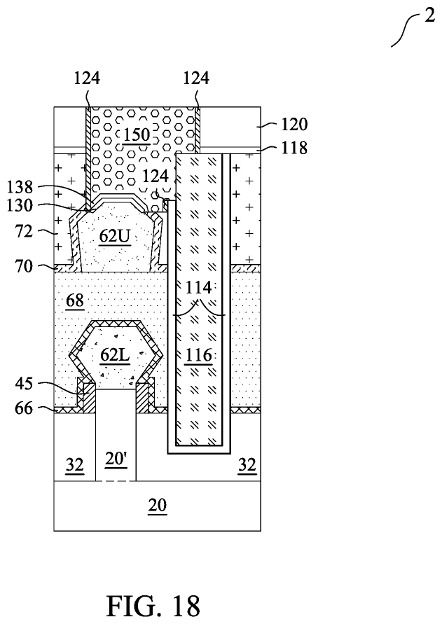

FIG. 17 illustrates the removal of the metal oxide layer 142. The process detail may be essentially the same as shown and discussed referring to in FIG. 12, and are not repeated herein. FIG. 18 illustrates the formation of contact plug 150. FIG. 19 illustrates the formation of silicide layer 158, backside contact plug 160, dielectric layer 164, and conductive features 162. The details of these processes are discussed referring to FIGS. 13 and 14, are not repeated herein.

The embodiments of the present disclosure have some advantageous features. By removing the metal layers formed in the contact openings, in subsequent nitriding process, no portion of the metal layer remains to be converted into metal nitride, which is hard to remove without causing damage to silicide. The wet etching process may be used to effectively remove the metal oxide and metal nitride on the contact plugs, and may desirably cause further reduction in the contact resistance.

In accordance with some embodiments of the present disclosure, a method comprises forming a source/drain region; forming a contact etch stop layer over the source/drain region; forming an inter-layer dielectric over the contact etch stop layer; forming a first contact plug in the inter-layer dielectric and the contact etch stop layer; performing an etching process to form a trench in the inter-layer dielectric and the contact etch stop layer, wherein the source/drain region and the first contact plug are exposed to the trench; performing a silicide formation process to form a silicide region on a surface of the source/drain region; etching a metal layer that is deposited on dielectric regions and in the trench, wherein the dielectric regions are exposed at a time the silicide formation process is started; and forming a second contact plug in the trench.

In an embodiment, the metal layer is etched in a plasma-free and a hydrogen-free (H₂-free) environment. In an embodiment, both of the silicide formation process and the etching the metal layer are performed using titanium chloride (TiCl₄) as a process gas, and during the silicide formation process, hydrogen (H₂) is used. In an embodiment, the method further comprises, after the silicide formation process, performing a nitrogen-treatment process to form a metal silicon nitride layer over the silicide region, wherein a metal nitride layer is formed on the first contact plug; and performing a wet etching process to remove the metal nitride layer. In an embodiment, the method further comprises performing a vacuum break process to form a metal oxide layer over the metal nitride layer, wherein the metal oxide layer is also removed by the wet etching process.

In an embodiment, the wet etching process is performed using a chemical solution comprising ozonated DI-water and hot DI-water. In an embodiment, the method further comprises selectively forming a passivation layer over the silicide region; and removing a metal compound layer from the first contact plug, wherein the metal compound layer is selected from the group consisting of a metal nitride layer, a metal oxide layer, and combinations thereof, and wherein when the metal compound layer is removed, the passivation layer is over the silicide region.

In an embodiment, the passivation layer is formed by soaking a wafer comprising the silicide region in a chemical solution, wherein a chemical in the chemical solution is adhered over the silicide region to form the passivation layer. In an embodiment, the chemical solution has a pH value in a range between about 2 and about 6. In an embodiment, the method further comprises, after the metal compound layer is removed, removing the passivation layer, wherein the second contact plug is formed after the passivation layer is removed.

In accordance with some embodiments of the present disclosure, a method comprises forming a lower source/drain region; forming a first contact etch stop layer over the lower source/drain region; forming a first inter-layer dielectric over the first contact etch stop layer; forming a upper source/drain region over the first inter-layer dielectric, wherein the upper source/drain region overlaps the lower source/drain region; forming a second contact etch stop layer over the upper source/drain region; forming a second inter-layer dielectric over the second contact etch stop layer; forming a first contact plug comprising a top surface higher than the upper source/drain region and a bottom surface lower than the lower source/drain region; and performing an etching process to form a contact opening in the second inter-layer dielectric and the second contact etch stop layer, wherein the first contact plug is exposed to the contact opening.

In an embodiment, the method further comprises forming a dielectric liner in the contact opening; forming a silicide region over and contacting the upper source/drain region, wherein a metal layer is simultaneously formed on the dielectric liner; performing a first etching process to remove the metal layer; performing a nitrogen-treatment process, wherein a metal silicon nitride layer is formed over the silicide region, and a metal nitride layer is formed over the first contact plug; performing a second etching process to etch the metal nitride layer and to reveal the first contact plug; and forming a second contact plug in the contact opening.

In an embodiment, the second etching process comprises a wet etching process. In an embodiment, the method further comprises, before the second etching process, forming a passivation layer to protect the metal silicon nitride layer when the metal nitride layer is etched. In an embodiment, the passivation layer is selectively formed by soaking the metal silicon nitride layer in a chemical solution, so that a chemical in the chemical solution is adhered over the metal silicon nitride layer.

In an embodiment, the passivation layer is selectively formed utilizing a zeta potential difference between the metal silicon nitride layer and the metal nitride layer. In an embodiment, the chemical solution comprises chemicals selected from the group consisting of phosphoric acid, silane coupling. agents, polyacrylic acid, and combinations thereof.

In accordance with some embodiments of the present disclosure, a method comprises forming a silicon-containing region; forming a silicide region over the silicon-containing region; forming a metal silicon nitride layer over the silicide region; and forming a metal feature over the metal silicon nitride layer, wherein after the metal feature is formed, an element selected from the group consisting of phosphorous, carbon, sulfur, fluorine, and combinations thereof is in the metal feature, the metal silicon nitride layer, and the silicide region.

In an embodiment, the element has a peak concentration at an interface between the metal silicon nitride layer and the metal feature. In an embodiment, the method further comprises, before the metal feature is formed, forming a passivation layer over the metal silicon nitride layer; performing an etching process to remove a metal nitride layer on an additional metal feature that is aside of the silicide region, wherein during the etching process, the passivation layer protects the metal silicon nitride layer; and removing the passivation layer, wherein the metal feature is formed after the passivation layer is removed. In an embodiment, the silicon-containing region is comprised in a source/drain region of a transistor, and wherein the silicide region is a source/drain silicide region of the transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a source/drain region;
forming a contact etch stop layer over the source/drain region;
forming an inter-layer dielectric over the contact etch stop layer;
performing an etching process to form a trench in the inter-layer dielectric and the contact etch stop layer, wherein the source/drain region and a metallic feature are exposed to the trench;
conducting a precursor to form a silicide layer on a surface of the source/drain region, wherein the precursor also causes a metal layer to be deposited on the metallic feature;
selectively etching the metal layer, wherein the silicide layer remains; and
after the metal layer is etched, performing a nitrogen-treatment process to form a metal silicon nitride layer over the silicide layer.

2. The method of claim 1 further comprising forming the metallic feature as a contact plug that penetrates through the inter-layer dielectric and the contact etch stop layer.

3. The method of claim 1 further comprising forming a source/drain contact plug in the trench.

4. The method of claim 3, wherein the source/drain contact plug is electrically connected to the source/drain region through the metal silicon nitride layer.

5. The method of claim 1, wherein the metal silicon nitride layer comprises TiSiN.

6. The method of claim 1, wherein the metal layer comprises an elemental metal that is in a non-metal-compound form.

7. The method of claim 6, wherein the metal layer comprises titanium.

8. The method of claim 1, wherein the metal layer is etched in a plasma-free and a hydrogen-free (H₂-free) environment.

9. The method of claim 1, wherein both the precursor for forming the silicide layer and an etching gas for etching the metal layer comprise titanium chloride (TiCl₄).

10. The method of claim 1, wherein in the nitrogen-treatment process, a metal nitride layer is also formed on the metallic feature.

11. The method of claim 10 further comprising performing a wet etching process to remove the metal nitride layer.

12. A method comprising:
forming a source/drain region;
forming a contact etch stop layer over the source/drain region;
forming an inter-layer dielectric over the contact etch stop layer;
forming a contact plug comprising a top surface higher than the source/drain region and a bottom surface lower than the source/drain region;
performing an etching process to form a contact opening in the inter-layer dielectric and the contact etch stop layer, wherein both the contact plug and the source/drain region are exposed to the contact opening;
forming a silicide region over and contacting the source/drain region, wherein a metal layer is simultaneously formed on the contact plug;
performing a first etching process to remove the metal layer;
performing a nitrogen-treatment process, wherein a metal silicon nitride layer is formed over the silicide region, and a metal nitride layer is formed over the contact plug;
performing a second etching process to etch the metal nitride layer and to reveal the contact plug; and
forming a second contact plug in the contact opening.

13. The method of claim 12, wherein the second etching process comprises a wet etching process.

14. The method of claim 13 further comprising, before the second etching process, forming a passivation layer to protect the metal silicon nitride layer when the metal nitride layer is etched.

15. The method of claim 14, wherein the passivation layer is selectively formed by soaking the metal silicon nitride layer in a chemical solution, so that a chemical in the chemical solution is adhered over the metal silicon nitride layer.

16. The method of claim 15, wherein the chemical solution comprises chemicals selected from the group consisting of phosphoric acid, silane coupling agents, polyacrylic acid, and combinations thereof.

17. A method comprising:
forming a silicon-containing region;
forming a silicide region over the silicon-containing region;
after the silicide region is formed, performing a first etching process to remove a titanium layer on a metallic feature, so that the metallic feature is revealed;
after the titanium layer is removed, forming a titanium silicon nitride layer over the silicide region and a metal nitride layer over the metallic feature; and
removing the metal nitride layer, wherein at a time after the metal nitride layer is removed, the titanium silicon nitride layer remains over the silicide region.

18. The method of claim 17, wherein the metal nitride layer comprise tungsten nitride.

19. The method of claim 17 further comprising:
before the metal feature is formed, forming a passivation layer over the titanium silicon nitride layer;
performing a second etching process to remove the metal nitride layer, wherein during the second etching process, the passivation layer protects the titanium silicon nitride layer; and
removing the passivation layer.

20. The method of claim 17, wherein the silicon-containing region is a source/drain region of a transistor, and wherein the silicide region is a source/drain silicide region of the transistor.
